(19) United States
(12) Patent Application Publication
(10) Pub. No.: US 2025/0093384 A1
(43) Pub. Date: Mar. 20, 2025

(54) PROBER, PERFORMANCE BOARD, PROBE CARD, AND SUBSTRATE INSPECTING APPARATUS

(71) Applicant: Kioxia Corporation, Tokyo (JP)

(72) Inventor: Hiroki KAMATA, Yokohama (JP)

(73) Assignee: Kioxia Corporation, Tokyo (JP)

(21) Appl. No.: 18/817,410

(22) Filed: Aug. 28, 2024

(30) Foreign Application Priority Data
Sep. 19, 2023 (JP) 2023-151725

(51) Int. Cl. G01R 1/073; G01R 31/28

(52) U.S. Cl. CPC G01R 1/07314; G01R 31/2831

(57) ABSTRACT

In one embodiment, a prober includes a stage configured to hold a substrate as an inspection object. The prober further includes a housing configured to hold a probe card that can be electrically connected to the substrate, and hold a performance board that can be electrically connected to the probe card. Moreover, the housing is configured to function as a ground line, and includes a connection path configured to electrically connect the probe card and the performance board.

### CROSS-REFERENCE TO RELATED APPLICATIONS

This application is based upon and claims the benefit of priority from the prior Japanese Patent Application No. 2023-151725, filed on Sep. 19, 2023, the entire contents of which are incorporated herein by reference.

### FIELD

Embodiments described herein relate to a prober, a performance board, a probe card, and a substrate inspecting apparatus.

### BACKGROUND

In a substrate inspecting apparatus that inspects a substrate such as a wafer, there is a problem that the number of pins used as an interface between parts (e.g., pogo pins) becomes a bottleneck to hinder an improvement of the performance of the substrate inspecting apparatus.

### BRIEF DESCRIPTION OF THE DRAWINGS

FIG. 1 is a sectional view showing a structure of a substrate inspecting apparatus of a first embodiment;

FIG. 2 is another sectional view showing the structure of the substrate inspecting apparatus of the first embodiment;

FIG. 3 is another sectional view showing the structure of the substrate inspecting apparatus of the first embodiment;

FIG. 4 is a plan view showing the structure of the substrate inspecting apparatus of the first embodiment;

FIG. 5 is a sectional view showing a structure of a substrate inspecting apparatus of a first modification of the first embodiment;

FIG. 6 is a sectional view showing a structure of a substrate inspecting apparatus of a second modification of the first embodiment;

FIG. 7 is a sectional view showing a structure of a substrate inspecting apparatus of a third modification of the first embodiment;

FIG. 8 is a sectional view showing a structure of a substrate inspecting apparatus of a second embodiment;

FIG. 9 is another sectional view showing the structure of the substrate inspecting apparatus of the second embodiment;

FIG. 10 is a plan view showing the structure of the substrate inspecting apparatus of the second embodiment;

FIG. 11 is a sectional view showing details of the structure of the substrate inspecting apparatus of the second embodiment; and

FIG. 12 is a sectional view showing a structure of a substrate inspecting apparatus of a modification of the second embodiment.

### DETAILED DESCRIPTION

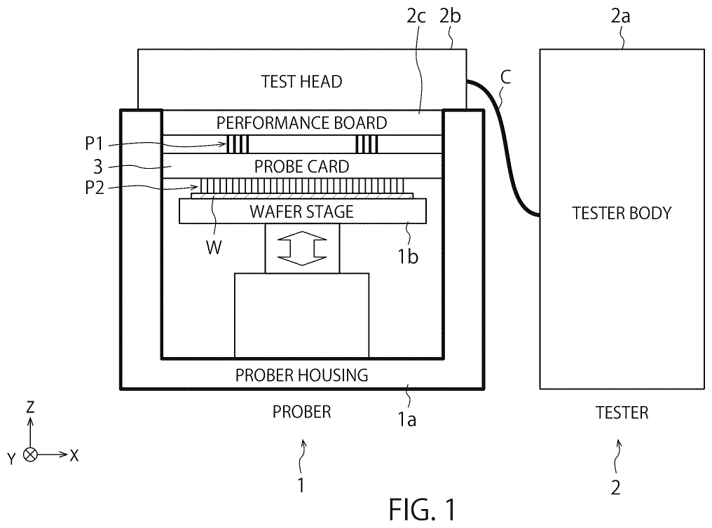

Embodiments will now be explained with reference to the accompanying drawings. In FIGS. 1 to 12, the same components will be denoted by the same reference signs, and redundant descriptions will be omitted.

In one embodiment, a prober includes a stage configured to hold a substrate as an inspection object. The prober further includes a housing configured to hold a probe card that can be electrically connected to the substrate, and hold a performance board that can be electrically connected to the probe card. Moreover, the housing is configured to function as a ground line, and includes a connection path configured to electrically connect the probe card and the performance board.

### FIRST EMBODIMENT

FIG. 1 is a sectional view showing a structure of a substrate inspecting apparatus of a first embodiment.

The substrate inspecting apparatus of the present embodiment is an apparatus that inspects a substrate W. Specifically, the substrate inspecting apparatus of the present embodiment inspects the substrate W in a wafer state. For example, after the inspection, the wafer is divided into a plurality of chips (semiconductor devices) by dicing. The inspection is also called a wafer test.

The substrate inspecting apparatus of the present embodiment includes a prober 1, a tester 2, and a probe card 3. The prober 1 includes a prober housing 1a and a wafer stage 1b. The tester 2 includes a tester body 2a, a test head 2b, and a performance board 2c.

FIG. 1 shows an X direction, a Y direction, and a Z direction which are perpendicular to one another. In this specification, a +Z direction is considered an upward direction and a −Z direction is considered a downward direction. The −Z direction may or may not coincide with a direction of gravitational force.

The prober 1 holds the substrate W as an inspection object, and holds various parts for inspection. Specifically, the prober housing 1a holds the test head 2b, the performance board 2c, and the probe card 3. In the present embodiment, the test head 2b, the performance board 2c, and the probe card 3 are supported by the prober housing 1a by being placed on the prober housing 1a. Details of the support by the prober housing 1a will be provided later. On the other hand, the wafer stage 1b holds the substrate W. In the present embodiment, the substrate W is supported by the wafer stage 1b by being placed on the wafer stage 1b. The prober 1 can move the substrate W being supported by the wafer stage 1b in an up-down direction (±Z direction) as depicted by an arrow in FIG. 1. The prober housing 1a and the wafer stage 1b are examples of the housing and the stage, respectively.

The tester 2 inspects the substrate W held by the prober 1. Specifically, the tester body 2a generates an inspection signal for inspecting the substrate W and outputs the inspection signal to the test head 2b via a cable C. The test head 2b receives the inspection signal from the tester body 2a via the cable C and outputs the inspection signal to the performance board 2c. The performance board 2c receives the inspection signal from the test head 2b and outputs the inspection signal to the probe card 3. In FIG. 1, the performance board 2c is removably mounted to the test head 2b.

The performance board 2c is electrically connected to the probe card 3 by a plurality of pins P1. The inspection signal outputted from the test head 2b is inputted to the probe card 3 via the pins P1. The pins P1 are, for example, pogo pins. The pins P1 may be held by the performance board 2c, held by the probe card 3, or held by the prober housing 1a.

The probe card 3 is a jig for electrically connecting the performance board 2c to the substrate W. The probe card 3 receives the inspection signal from the performance board 2c and outputs the inspection signal to the substrate W.

The probe card 3 is electrically connected to the substrate W by a plurality of pins P2. The inspection signal outputted from the probe card 3 is inputted to the substrate W via the pins P2. The pins P2 are, for example, probe needles. The pins P2 are, for example, held by the probe card 3.

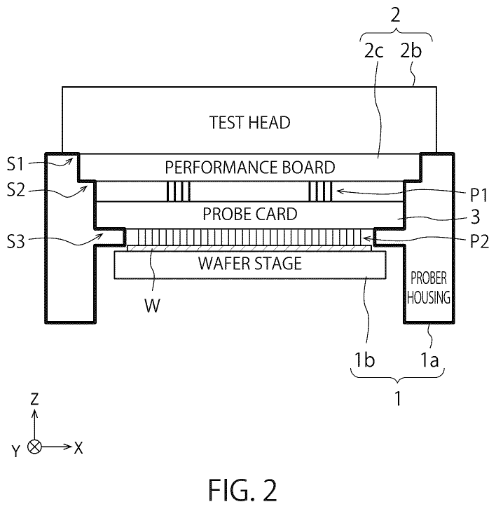

FIG. 2 is another sectional view showing the structure of the substrate inspecting apparatus of the first embodiment.

FIG. 2 shows a shape of the prober housing 1a of the present embodiment in detail. The prober housing 1a of the present embodiment includes an upper surface S1, an upper surface S2 provided at a lower position than the upper surface S1, and an upper surface S3 provided at a lower position than the upper surface S2. As shown in FIG. 2, the test head 2b is placed on the upper surface S1, the performance board 2c is placed on the upper surface S2, and the probe card 3 is placed on the upper surface S3. In the present embodiment, by lifting the test head 2b, the performance board 2c, and the probe card 3 off the prober housing 1a, the test head 2b, the performance board 2c, and the probe card 3 can be detached from the prober housing 1a.

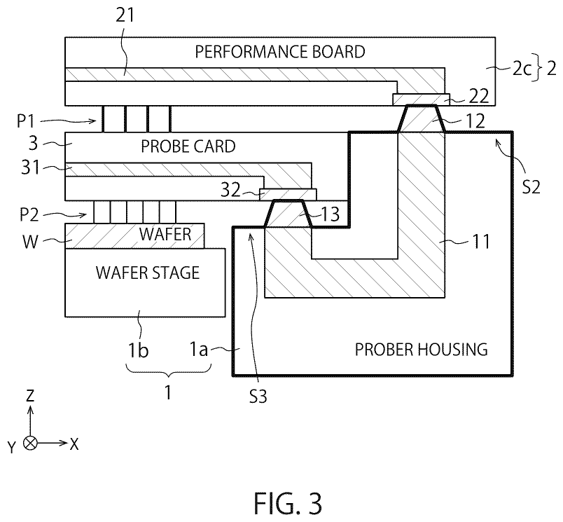

FIG. 3 is another sectional view showing the structure of the substrate inspecting apparatus of the first embodiment. FIG. 3 shows a structure of a ground line (GND line) in the substrate inspecting apparatus of the present embodiment.

As shown in FIG. 3, the prober housing 1a includes a ground line 11, a bump 12, and a bump 13. The performance board 2c includes a ground line 21 and a pad 22. The probe card 3 includes a ground line 31 and a pad 32.

The ground line 11, the bump 12, and the bump 13 form a connection path that electrically connects the performance board 2c and the probe card 3 to each other. The ground line 11, the bump 12, and the bump 13 function as a ground line in the prober housing 1a. In FIG. 3, the bump 12 is provided at one end of the ground line 11 and the bump 13 is provided at another end of the ground line 11. The bumps 12 and 13 are used as connecting terminals of the ground line in the prober housing 1a. For example, the bumps 12 and 13 are formed by deposition of electroless nickel plating and have high hardness, resistance to abrasion, and low resistance. For example, the ground line 11, the bump 12, and the bump 13 are formed of a conductive material such as metal.

The bump 12 forms a portion of the upper surface S2 of the prober housing 1a. The performance board 2c of the present embodiment is placed on the bump 12 and, accordingly, electrically connected to the bump 12. The bump 12 functions as a supporting portion that supports the performance board 2c and also functions as a connecting portion that electrically connects the performance board 2c to the ground line 11. The bump 12 is an example of the first connecting portion and the first supporting portion.

The bump 13 forms a portion of the upper surface S3 of the prober housing 1a. The probe card 3 of the present embodiment is placed on the bump 13 and, accordingly, electrically connected to the bump 13. The bump 13 functions as a supporting portion that supports the probe card 3 and also functions as a connecting portion that electrically connects the probe card 3 to the ground line 11. The bump 13 is an example of the second connecting portion and the second supporting portion.

The ground line 11 forms a path that electrically connects the bump 12 and the bump 13 to each other in the prober housing 1a. By placing the performance board 2c on the bump 12 and placing the probe card 3 on the bump 13, for example, the present embodiment makes it possible to electrically connect the substrate W to the ground lines 11, 21, and 31.

The ground line 21 and the pad 22 function as a ground line in the performance board 2c. In FIG. 3, the pad 22 is provided at one end of the ground line 21. The pad 22 is used as a connecting terminal of the ground line in the performance board 2c. For example, the ground line 21 and the pad 22 are formed of a conductive material such as metal.

As shown in FIG. 3, the pad 22 forms a portion of a lower surface of the performance board 2c. The pad 22 of the present embodiment is placed on the bump 12 and, accordingly, electrically connected to the bump 12. The pad 22 functions as a supported portion that is supported by the bump 12 and also functions as a connecting portion that electrically connects the bump 12 to the ground line 21. The pad 22 is an example of the first line connecting portion and the first supported portion.

The ground line 21 is laid in the performance board 2c. For example, the ground line 21 is electrically connected to the ground line in the test head 2b and to the ground line in the tester body 2a. The ground line 21 is an example of the first line.

The ground line 31 and the pad 32 function as a ground line in the probe card 3. In FIG. 3, the pad 32 is provided at one end of the ground line 31. The pad 32 is used as a connecting terminal of the ground line in the probe card 3. For example, the ground line 31 and the pad 32 are formed of a conductive material such as metal.

As shown in FIG. 3, the pad 32 forms a portion of a lower surface of the probe card 3. The pad 32 of the present embodiment is placed on the bump 13 and, accordingly, electrically connected to the bump 13. The pad 32 functions as a supported portion that is supported by the bump 13 and also functions as a connecting portion that electrically connects the bump 13 to the ground line 31. The pad 32 is an example of the second line connecting portion and the second supported portion.

The ground line 31 is laid in the probe card 3. For example, the ground line 31 can be electrically connected to the ground line in the substrate W via the pins P2. The ground line 31 is an example of the second line.

Next, details of the ground lines in the substrate inspecting apparatus of the present embodiment will be described with continued reference to FIG. 3.

In the present embodiment, the ground line 21 in the performance board 2c and the ground line 31 in the probe card 3 are electrically connected by the ground line 11 in the prober housing 1a instead of the pins P1. When the ground line 21 and the ground line 31 are electrically connected by the pins P1, the following problem arises.

In recent years, the number of pins P1 between the performance board 2c and the probe card 3 is on the rise. However, there is an upper limit to the number of pins P1 that can be arranged between the performance board 2c and the probe card 3. Therefore, the number of pins P1 becomes a bottleneck to hinder an improvement of the performance of the substrate inspecting apparatus.

For example, the upper limit of the number of pins P1 becomes a bottleneck when satisfying demands to increase the number of chips that can be simultaneously inspected. As a result, it becomes difficult to increase the number of pins P1 and improve inspection efficiency of the substrate W.

In addition, the upper limit of the number of pins P1 becomes a bottleneck when satisfying demands to increase the numbers of power lines, ground lines, and signal lines of each chip. As a result, it becomes difficult to achieve both an increase in the numbers of the lines and an improvement in the inspection efficiency of the substrate W.

Furthermore, the upper limit of the number of pins P1 becomes a bottleneck when satisfying demands to increase a consumption current of each chip during inspection. This is because there has been an emergence of inspection items that require a large current. However, increasing the current consumption value necessitates increasing the number or a sectional area of ground lines in order to release a large consumed current. As a result, it becomes difficult to achieve both an increase in the consumption current and an improvement in the inspection efficiency of the substrate W.

In order to address these problems, conceivably, the pins P1 may be made thinner or intervals among the pins P1 may be made smaller. However, making the pins P1 thinner creates a risk of increasing electrical resistance of the pins P1. In addition, making the intervals among the pins P1 smaller creates a risk of an occurrence of crosstalk among the pins P1.

On the other hand, in the present embodiment, the ground line 21 in the performance board 2c and the ground line 31 in the probe card 3 are electrically connected by the ground line 11 in the prober housing 1a instead of the pins P1. Therefore, by eliminating the need for the pins P1 for grounding, the present embodiment makes it possible to reduce the number of pins P1 between the performance board 2c and the probe card 3.

While increasing the number or a sectional area of the pins P1 lines is difficult, increasing the number or a sectional area of the ground lines 11 in the prober housing 1a is easy. This is because the prober housing 1a has spatial allowance. Therefore, by increasing the number or a sectional area of the ground lines 11 in the prober housing 1a, the present embodiment makes it possible to address the problem related to a large current described above.

Note that the bumps 12 and 13 may be replaced with other connecting portions. In addition, the pads 22 and 32 may be replaced with other connecting portions. For example, the bumps 12 and 13 may be replaced with pads and the pads 22 and 32 may be replaced with bumps. Furthermore, the prober housing 1a and the performance board 2c may be electrically connected by pogo pins similar to the pins P1 instead of by the bump 12 and the pad 22. In a similar manner, the prober housing 1a and the probe card 3 may be electrically connected by pogo pins similar to the pins P1 instead of by the bump 13 and the pad 32.

In addition, the prober housing 1a may hold the performance board 2c and the probe card 3 by a mode other than “placement” and “support” described earlier. For example, the performance board 2c and the probe card 3 may be held in the substrate inspecting apparatus by vacuum suction. In this case, the prober housing 1a holds the performance board 2c by coming into contact with the performance board 2c and also indirectly holds the probe card 3 by holding the performance board 2c that sucks the probe card 3 by vacuum suction. Furthermore, the prober housing 1a, the performance board 2c, and the probe card 3 in this case desirably include connecting portions that enable airtightness for vacuum suction to be secured instead of the bumps 12 and 13 and the pads 22 and 32. An anisotropic rubber contactor is an example of such a connecting portion. The vacuum suction may be performed by the prober housing 1a or by another component in the substrate inspecting apparatus. For example, the prober housing 1a may hold the performance board 2c and the probe card 3 by sucking the performance board 2c and the probe card 3 by vacuum suction and by supporting the performance board 2c.

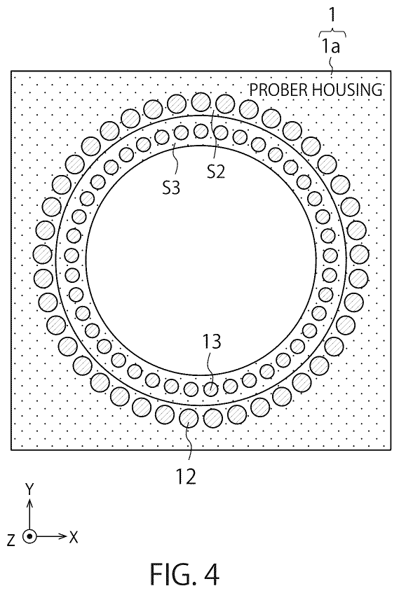

FIG. 4 is a plan view showing the structure of the substrate inspecting apparatus of the first embodiment.

FIG. 4 shows the upper surfaces S2 and S3 of the prober housing 1a, the plurality of bumps 12 that form a portion of the upper surface S2, and the plurality of bumps 13 that form a portion of the upper surface S3. The bump 12 shown in FIG. 3 is one of these bumps 12 and the bump 13 shown in FIG. 3 is one of these bumps 13. In FIG. 4, the upper surface S2 other than the bumps 12 and the upper surface S3 other than the bumps 13 are indicated by dot hatchings.

The upper surface S3 of the present embodiment has an annular shape and has a circular inner circumference and outer circumference in plan view. The plurality of bumps 13 of the upper surface S3 are arranged in an annular shape along the inner circumference and the outer circumference. In addition, the upper surface S2 of the present embodiment has a circular inner circumference in plan view. The plurality of bumps 12 of the upper surface S2 are arranged in an annular shape along the inner circumference.

The prober housing 1a may include only one bump 12 or may include a plurality of bumps 12. However, when there is only one bump 12, there is a risk that the performance board 2c on the bump 12 may tilt or electrical resistance of the bump 12 may rise. Therefore, the prober housing 1a desirably includes a plurality of bumps 12. This similarly applies to the bumps 13.

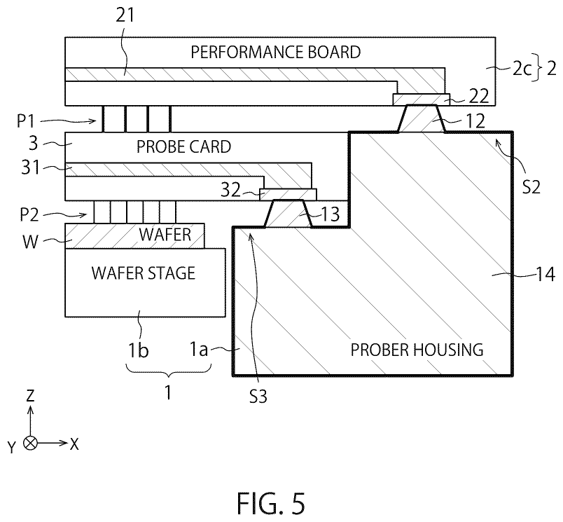

FIG. 5 is a sectional view showing a structure of a substrate inspecting apparatus of a first modification of the first embodiment. The substrate inspecting apparatus of the present modification has a structure similar to the structure shown in FIG. 3. However, a major portion of the prober housing 1a of the present modification is formed of a conductive material 14 and the conductive material 14 functions as a ground line in the prober housing 1a. The conductive material 14 forms a path that electrically connects the bump 12 and the bump 13 to each other.

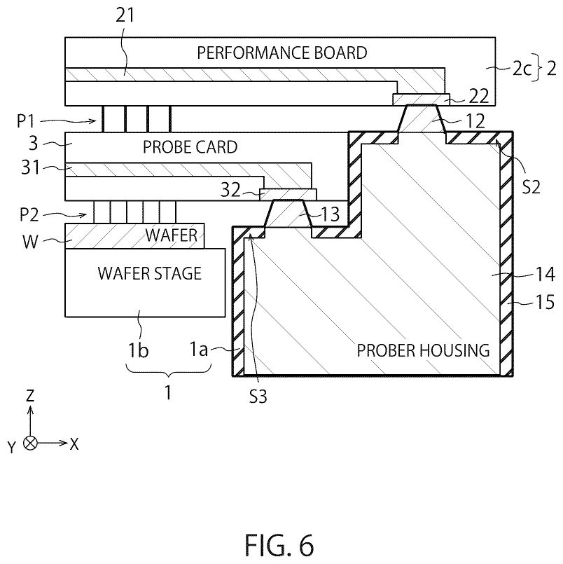

FIG. 6 is a sectional view showing a structure of a substrate inspecting apparatus of a second modification of the first embodiment.

The substrate inspecting apparatus of the present modification has a structure similar to the structure shown in FIG. 5. However, the prober housing 1a of the present modification includes the conductive material 14 described above and an insulation material 15 provided on a surface of the conductive material 14. Accordingly, an unintended occurrence of a short circuit of the conductive material 14 can be suppressed.

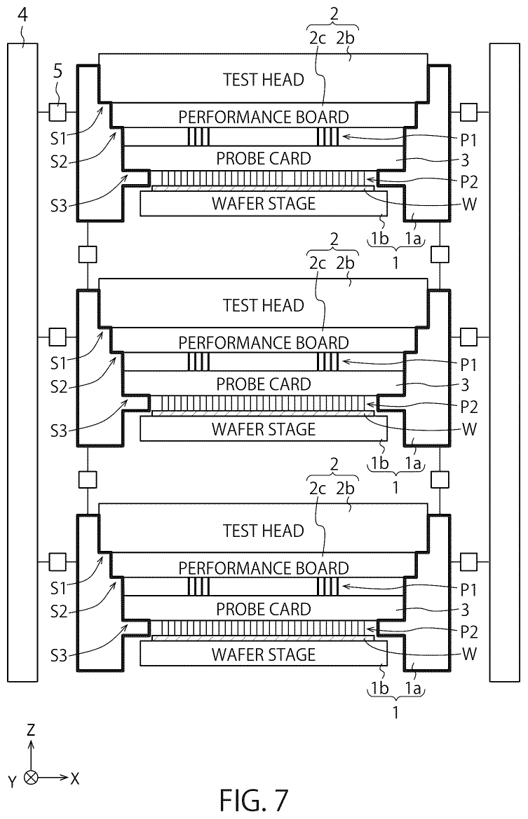

FIG. 7 is a sectional view showing a structure of a substrate inspecting apparatus of a third modification of the first embodiment.

The substrate inspecting apparatus of the present modification includes plurality of sets of the prober 1, the tester 2, and the probe card 3. The prober 1, the tester 2, and the probe card 3 of each set roughly have similar structures to the prober 1, the tester 2, and the probe card 3 (FIGS. 1 to 4) of the first embodiment. Accordingly, a plurality of substrates W can be simultaneously inspected.

The substrate inspecting apparatus of the present modification further includes a ground plate 4 arranged near the probers 1. The ground plate 4 is formed of a conductive material and functions as a ground line. The ground plate 4 is an example of the ground member.

The substrate inspecting apparatus of the present modification further includes a plurality of filters 5 provided between the probers 1 and the ground plate 4 or among the probers 1. Each of the former filters 5 is electrically connected to the prober housing 1a of one prober 1 and to the ground plate 4. Each of the latter filters 5 is electrically connected to the prober housing 1a of one prober 1 and to the prober housing 1a of another prober 1. Each of the former filters 5 is an example of the first filter and each of the latter filters 5 is an example of the second filter.

Each of the filters 5 has a predetermined mutual inductance. Accordingly, an effect of EMI (Electro Magnetic Interference) noise can be eliminated from each prober 1 and an effect of EMI noise among the probers 1 can be suppressed. In addition, by providing the ground plate 4 as a measure against EMI noise and the filters 5 that are electrically connected to the ground plate 4, the present modification makes it possible to reduce the effect of EMI noise on each prober 1 from an outside environment.

As described above, in the present embodiment, the ground line 21 in the performance board 2c and the ground line 31 in the probe card 3 are electrically connected by the ground line 11 in the prober housing 1a. Therefore, the present embodiment makes it possible to realize a suitable interface such as enabling the number of pins P1 that are used as an interface between the performance board 2c and the probe card 3 to be reduced.

### SECOND EMBODIMENT

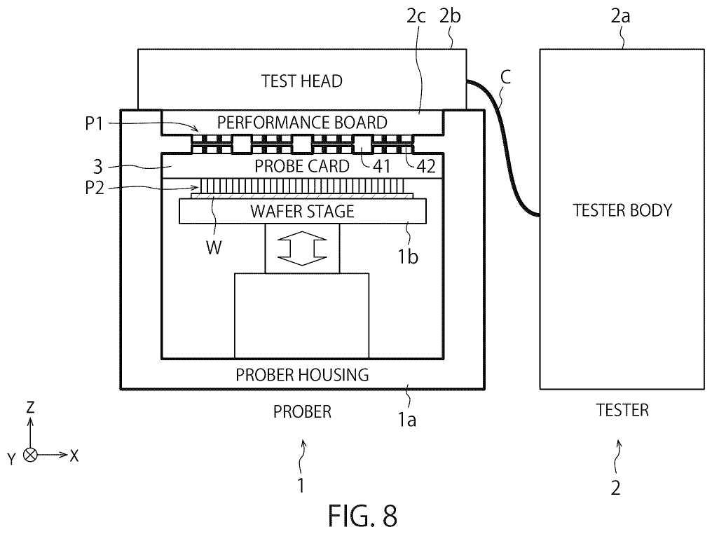

FIG. 8 is a sectional view showing a structure of a substrate inspecting apparatus of a second embodiment.

The substrate inspecting apparatus of the present embodiment has a structure similar to the substrate inspecting apparatus (FIGS. 1 to 4) of the first embodiment. However, the prober housing 1a of the present embodiment includes a frame 41 and a plurality of blocks 42.

The frame 41 has a plate-like shape that spreads in an X direction and a Y direction and includes a plurality of openings in plan view. Each block 42 is held by the frame 41 by being fitted into one opening among the openings. Each block 42 of the present embodiment holds the plurality of pins P1 that electrically connect the performance board 2c and the probe card 3 to each other. The pins P1 are, for example, pogo pins. Each pin P1 is an example of the connecting member.

For example, the frame 41 is formed of a conductive material such as metal. For example, each block 42 is formed of an insulation material such as resin. The performance board 2c and the probe card 3 of the present embodiment may be held by vacuum suction in the substrate inspecting apparatus. In addition, the performance board 2c of the present embodiment is placed on the frame 41 and, accordingly, held by the prober housing 1a.

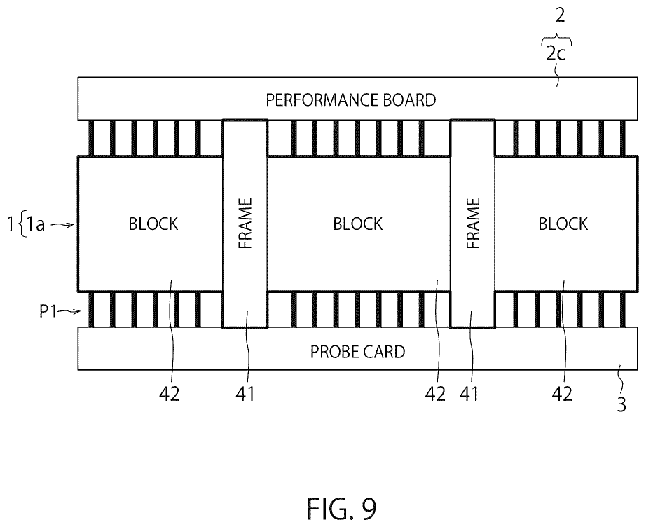

FIG. 9 is another sectional view showing the structure of the substrate inspecting apparatus of the second embodiment.

FIG. 9 shows, in an enlarged manner, the frame 41 and the block 42 of the present embodiment. As shown in FIG. 9, the frame 41 of the present embodiment is in contact with a lower surface of the performance board 2c and in contact with an upper surface of the probe card 3. Accordingly, horizontality of the performance board 2c and the probe card 3 can be guaranteed by the frame 41. Each block 42 is fitted into one of the plurality of openings of the frame 41.

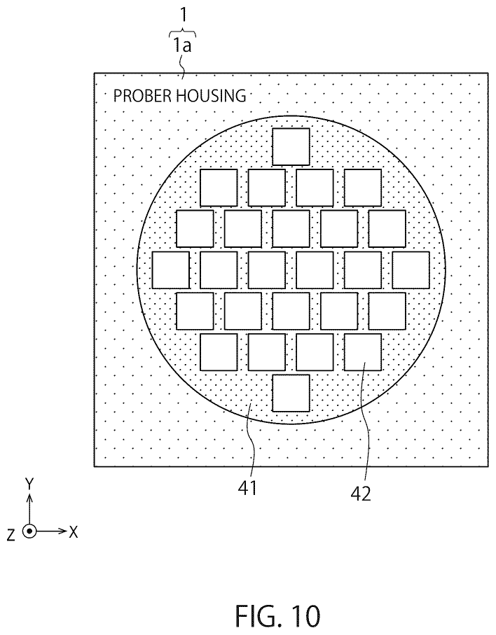

FIG. 10 is a plan view showing the structure of the substrate inspecting apparatus of the second embodiment.

In FIG. 10, the frame 41 is indicated by dense dot hatchings and the prober housing 1a other than the frame 41 and the block 42 is indicated by sparse dot hatchings. As shown in FIG. 10, the frame 41 has a plurality of openings, and each block 42 is fitted into one of the openings.

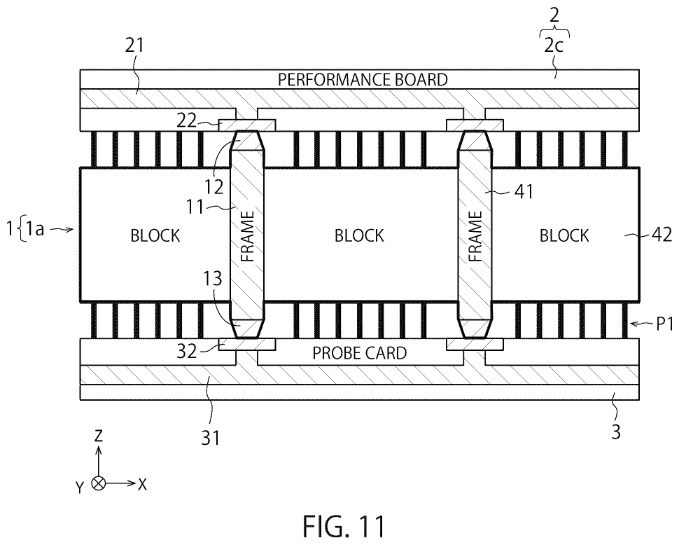

FIG. 11 is a sectional view showing details of the structure of the substrate inspecting apparatus of the second embodiment.

Compared to the substrate inspecting apparatus of the first embodiment having the structure shown in FIG. 3, the substrate inspecting apparatus of the present embodiment has a structure shown in FIG. 11. The performance board 2c and the probe card 3 of the present embodiment have similar structures to the performance board 2c and the probe card 3 of the first embodiment. However, in the present embodiment, the pad 22 forms a portion of the lower surface of the performance board 2c above the frame 41 and the pad 32 forms a portion of the upper surface of the probe card 3 below the frame 41.

In addition, the ground line 11, the bump 12, and the bump 13 of the present embodiment form a connection path that electrically connects the performance board 2c and the probe card 3 to each other in the frame 41. In FIG. 11, the bump 12 is provided at an upper end of the ground line 11 and the bump 13 is provided at a lower end of the ground line 11.

The bump 12 of the present embodiment forms an upper end of the frame 41. The performance board 2c (the pad 22) of the present embodiment is in contact with the bump 12 and, accordingly, electrically connected to the bump 12. The bump 12 of the present embodiment functions as a connecting portion that electrically connects the performance board 2c to the ground line 11. In addition, the bump 12 of the present embodiment functions as a supporting portion that supports the performance board 2c.

The bump 13 of the present embodiment forms a lower end of the frame 41. The probe card 3 (the pad 32) of the present embodiment is in contact with the bump 13 and, accordingly, electrically connected to the bump 13. The bump 13 of the present embodiment functions as a connecting portion that electrically connects the probe card 3 to the ground line 11.

The ground line 11 of the present embodiment forms a path that electrically connects the bump 12 and the bump 13 to each other in the frame 41. By bringing the bump 12 into contact with the performance board 2c and the bump 13 into contact with the probe card 3, for example, the present embodiment makes it possible to electrically connect the substrate W to the ground lines 11, 21, and 31.

While the ground line 11, the bump 12, and the bump 13 of the present embodiment constitute a portion of the frame 41, portions of the ground line 11, the bump 12, and the bump 13 of the present embodiment may constitute a portion of the prober housing 1a other than the frame 41.

In addition, in the present embodiment, the entire frame 41 other than the bumps 12 and 13 may be used as the ground line 11. In this case, the entire frame 41 other than the bumps 12 and 13 is formed of a conductive material, the bump 12 is formed on an upper surface of the conductive material, and the bump 13 is formed on a lower surface of the conductive material. Accordingly, the conductive material can be used in a similar mode to the conductive material 14 shown in FIG. 5 and a structure similar to the ground line of the prober housing 1a shown in FIG. 5 can be realized.

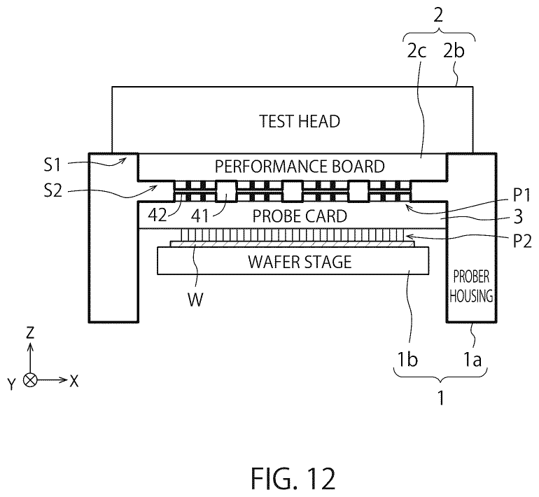

FIG. 12 is a sectional view showing a structure of a substrate inspecting apparatus of a modification of the second embodiment.

The substrate inspecting apparatus of the present modification has a structure shown in FIG. 11 instead of the structure shown in FIG. 2 (first embodiment). The prober housing 1a of the present modification includes the upper surface S1 that supports the test head 2b and the upper surface S2 that supports the performance board 2c but not the upper surface S3 that supports the probe card 3. Since the performance board 2c and the probe card 3 are held in the substrate inspecting apparatus by vacuum suction in the present modification, the upper surface S3 is not provided in the prober housing 1a. In addition, the upper surface S2 may be provided only on the frame 41 or may also be provided in the prober housing 1a other than the frame 41.

As described above, in the present embodiment, the ground line 21 in the performance board 2c and the ground line 31 in the probe card 3 are electrically connected by the ground line 11 in the frame 41. Therefore, the present embodiment makes it possible to realize a suitable interface such as enabling the number of pins P1 that are used as an interface between the performance board 2c and the probe card 3 to be reduced in a similar manner to the first embodiment.

While the bumps 12 and 13 are handled as components in the frame 41 or, in other words, a portion of the frame 41 in the description of the present embodiment, the bumps 12 and 13 may be handled as components other than the frame 41. This also applies to case where the prober housing 1a includes connecting portions other than the bumps 12 and 13.

While certain embodiments have been described, these embodiments have been presented by way of example only, and are not intended to limit the scope of the inventions. Indeed, the novel probers, boards, cards and apparatuses described herein may be embodied in a variety of other forms; furthermore, various omissions, substitutions and changes in the form of the novel probers, boards, cards and apparatuses described herein may be made without departing from the spirit of the inventions. The accompanying claims and their equivalents are intended to cover such forms or modifications as would fall within the scope and spirit of the inventions.

1. A prober comprising:
a stage configured to hold a substrate as an inspection object; and
a housing configured to hold a probe card that can be electrically connected to the substrate, and hold a performance board that can be electrically connected to the probe card,
wherein the housing is configured to function as a ground line, and includes a connection path configured to electrically connect the probe card and the performance board.

2. The prober of claim 1, wherein the connection path includes:
a first connecting portion configured to electrically connect the connection path to the performance board;
a second connecting portion configured to electrically connect the connection path to the probe card; and
a path configured to electrically connect the first connecting portion and the second connecting portion.

3. The prober of claim 2, wherein
the first connecting portion is a first supporting portion configured to support the performance board to be electrically connected to the performance board; and
the second connecting portion is a second supporting portion configured to support the probe card to be electrically connected to the probe card.

4. The prober of claim 3, wherein
the first supporting portion is a bump configured to support the performance board; and
the second supporting portion is a bump configured to support the probe card.

5. The prober of claim 1, wherein
the performance board includes:
a first line configured to function as a ground line; and
a first line connecting portion configured to electrically connect the first line to the connection path, and
the probe card includes:
a second line configured to function as a ground line; and
a second line connecting portion configured to electrically connects the second line to the connection path.

6. The prober of claim 5, wherein
the first line connecting portion is a first supported portion configured to be supported by the housing to be electrically connected to the connection path, and
the second line connecting portion is a second supported portion configured to be supported by the housing to be electrically connected to the connection path.

7. The prober of claim 6, wherein each of the first supported portion and the second supported portion is a pad configured to be supported by the housing.

8. The prober of claim 1, wherein
the housing includes a frame configured to hold a plurality of blocks, and
each of the blocks is configured to hold a connecting member configured to electrically connect the probe card and the performance board.

9. The prober of claim 8, wherein at least a portion of the connection path is provided in the frame.

10. The prober of claim 8, wherein the connection path includes:
a first connecting portion configured to electrically connect the connection path to the performance board;
a second connecting portion configured to electrically connect the connection path to the probe card; and
a path provided in the frame, and configured to electrically connect the first connecting portion and the second connecting portion.

11. The prober of claim 10, wherein
the first connecting portion is a bump configured to contact the performance board; and
the second connecting portion is a bump configured to contact the probe card.

12. The prober of claim 8, wherein
the performance board includes:
a first line configured to function as a ground line; and
a first line connecting portion configured to electrically connect the first line to the connection path, and
the probe card includes:
a second line configured to function as a ground line; and
a second line connecting portion configured to electrically connect the second line to the connection path.

13. The prober of claim 12, wherein each of the first line connecting portion and the second line connecting portion is a pad configured to contact the housing.

14. A performance board that can be electrically connected to a substrate as an inspection object via a probe card, comprising:
a first line configured to function as a ground line; and
a first line connecting portion configured to electrically connect the first line to a housing of a prober configured to hold the substrate.

15. The board of claim 14, wherein the first line connecting portion is a first supported portion configured to be supported by the housing to be electrically connected to the housing.

16. A probe card that can be electrically connected to a substrate as an inspection object, comprising:
a second line configured to function as a ground line; and
a second line connecting portion configured to electrically connect the second line to a housing of a prober configured to hold the substrate.

17. The card of claim 16, wherein the second line connecting portion is a second supported portion configured to be supported by the housing to be electrically connected to the housing.

18. A substrate inspecting apparatus comprising:
a probe card that can be electrically connected to a substrate as an inspection object;
a tester including a performance board that can be electrically connected to the probe card; and
a prober including a stage configured to hold the substrate, and a housing configured to hold the probe card and the performance board,
wherein the housing is configured to function as a ground line, and includes a connection path configured to electrically connects the probe card and the performance board.

19. The apparatus of claim 18, further comprising:
a ground member provided in a vicinity of the prober, and configured to function as a ground line; and
a first filter provided between the prober and the ground member, and having a predetermined mutual inductance.

20. The apparatus of claim 18, further comprising a second filter provided between the prober and another prober in the substrate inspecting apparatus, and having a predetermined mutual inductance.
